(19) United States
(12) Patent Application Publication
(10) Pub. No.: US 2025/0393480 A1
(43) Pub. Date: Dec. 25, 2025

(54) SERPENTINE ELECTRODE FOR MEMORY DEVICES

(71) Applicant: International Business Machines Corporation, Armonk, NY (US)

(72) Inventors: Oscar van der Straten, Guilderland Center, NY (US); Willie Lester Muchrison, JR., Troy, NY (US); Mark Lucarelli, Schenectady, NY (US); Chih-Chao Yang, Glenmont, NY (US)

(21) Appl. No.: 18/750,269

(22) Filed: Jun. 21, 2024

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A bottom electrode having a serpentine pattern is provided for a memory device in which the bottom electrode is located between a MTJ-containing pillar and a first electrically conductive structure.

### BACKGROUND

The present application relates to a memory device, and more particularly to a memory device including a bottom electrode having a serpentine pattern that is located beneath a magnetic tunnel junction (MTJ)-containing pillar.

Magnetoresistive random access memory (MRAM) is a non-volatile random access memory technology in which data is stored by magnetic storage elements. These elements are typically formed from two ferromagnetic plates, each of which can hold a magnetization, separated by a thin dielectric layer (i.e., a tunnel barrier). One of the two plates is a permanent magnetic set to a particular polarity (i.e., a magnetic reference layer); the other plate's magnetization can be changed to match that of an external field to store memory (i.e., a magnetic free layer). Such a configuration is known as a MTJ-containing pillar. In leading-edge or neuromorphic computing systems, an MTJ-containing pillar is typically embedded within a back-end-of-the-line (BEOL) structure.

### SUMMARY

A bottom electrode having a serpentine pattern is provided for a memory device in which the bottom electrode is located between a MTJ-containing pillar and a first electrically conductive structure.

In one embodiment of the present application, the memory device includes a first electrically conductive structure, a metal cap located on the first electrically conductive structure, a MTJ-containing pillar located above the metal cap, a bottom electrode having a serpentine pattern located between the metal cap and the MTJ-containing pillar in which the bottom electrode has a bottommost surface in contact with the metal cap and a topmost surface in contact with the MTJ-containing pillar, a top electrode located on the MTJ-containing pillar, and a second electrically conductive structure electrically connected to the top electrode.

In another embodiment of the present application, the memory device includes a first electrically conductive structure, a metal cap located on the first electrically conductive structure, a MTJ-containing pillar located above the metal cap, a multilayered bottom electrode structure having a serpentine pattern located between the metal cap and the MTJ-containing pillar in which the multilayered bottom electrode structure has a bottommost bottom electrode in contact with the metal cap and a topmost bottom electrode in contact with the MTJ-containing pillar, a top electrode located on the MTJ-containing pillar, and a second electrically conductive structure electrically connected to the top electrode.

### BRIEF DESCRIPTION OF THE DRAWINGS

FIG. 1 is a cross sectional view of an exemplary structure that can be employed in the present application, the exemplary structure including a first electrically conductive structure embedded in a first interlayer dielectric (ILD) layer, and a dielectric cap located on the first ILD layer and the first electrically conductive structure.

FIG. 2 is a cross sectional view of the exemplary structure of FIG. 1 after patterning the dielectric cap to physically expose the first electrically conductive structure, and forming a metal cap on the physically exposed first electrically conductive structure and adjacent to the patterned dielectric cap.

FIG. 3 is a cross sectional view of the exemplary structure of FIG. 2 after forming a second ILD layer on the patterned dielectric cap and the metal cap.

FIG. 4 is a cross sectional view of the exemplary structure of FIG. 3 after forming a first patterned hard mask on the second ILD layer.

FIG. 5 is a cross sectional view of the exemplary structure of FIG. 4 after performing an etch to transfer the pattern provided by the first patterned hard mask into the second ILD layer, and removing the first patterned hard mask.

FIG. 6 is a cross sectional view of the exemplary structure of FIG. 5 after forming a bottom electrode material containing layer having a serpentine pattern on the patterned second ILD layer.

FIG. 7 is a cross sectional view of the exemplary structure of FIG. 6 after forming a gap filling ILD layer in the gaps provided by the serpentine pattern of the bottom electrode containing layer.

FIG. 8 is a cross sectional view of the exemplary structure of FIG. 7 after forming a second patterned hard mask on a portion of the bottom electrode containing layer and on the gap filling ILD layer that is located in the gaps provided by the serpentine pattern of the bottom electrode containing layer.

FIG. 9 is a cross sectional view of the exemplary structure of FIG. 8 after removing physically exposed portions of the bottom electrode containing layer that are not protected by the second patterned hard mask, and removing the second patterned hard mask to reveal a bottom electrode having a serpentine pattern in which the gaps provided by the serpentine pattern are filled with the gap filling ILD layer.

FIG. 10 is a cross sectional view of the exemplary structure of FIG. 9 after forming a third ILD layer on the second ILD layer to provide a multi-layered ILD containing region.

FIG. 11 is a cross sectional view of the exemplary structure of FIG. 10 after forming a MTJ-containing stack including a blanket bottom magnetic material containing layer, a blanket tunnel barrier layer and a blanket upper magnetic material containing layer.

FIG. 12 is a cross sectional view of the exemplary structure of FIG. 11 after forming a top electrode material containing layer on the MTJ-containing stack.

FIG. 13 is a cross sectional view of the exemplary structure of FIG. 12 after forming a third patterned hard mask on the top electrode material containing layer.

FIG. 14 is a cross sectional view of the exemplary structure of FIG. 13 after etching the top electrode material containing layer and the MTJ-containing stack to provide a top electrode and a MTJ-containing pillar, respectively, in which the etching utilizes the third patterned hard mask as an etch mask, and removing the third patterned hard mask.

FIG. 15 is a cross sectional view of the exemplary structure of FIG. 14 after forming an encapsulation liner on sidewalls of the top electrode and the MTJ-containing pillar.

FIG. 16 is a cross sectional view of the exemplary structure of FIG. 15 after forming a fourth ILD layer adjacent to the encapsulation liner and on top of the top electrode.

FIG. 17 is a cross sectional view of the exemplary structure of FIG. 16 after forming a second electrically conductive structure in the fourth ILD layer and in electrical contact with the top electrode.

FIG. 18 is a cross sectional view of the exemplary structure of FIG. 5 after forming a first bottom electrode material containing layer having a serpentine pattern on the patterned second ILD layer, and a second bottom electrode material containing layer having a serpentine pattern on the first bottom electrode material containing layer.

FIG. 19 is a cross sectional view of the exemplary structure of FIG. 18 after forming a gap filling ILD layer in the gaps provided by the serpentine pattern of the second bottom electrode containing layer.

FIG. 20 is a cross sectional view of the exemplary structure of FIG. 19 after forming a second patterned hard mask on a portion of the second bottom electrode containing layer and on the gap filling ILD layer that is located in the gaps provided by the serpentine pattern of the second bottom electrode containing layer.

FIG. 21 is a cross sectional view of the exemplary structure of FIG. 20 after removing physically exposed portions of the second bottom electrode containing layer and underlying portions of the first bottom electrode containing layer that are not protected by the second patterned hard mask, and removing the second patterned hard mask to reveal a second bottom electrode having a serpentine pattern in which the gaps provided by the serpentine pattern are filled with the gap filling ILD layer, and a first bottom electrode having a serpentine pattern located beneath the second bottom electrode; the first bottom electrode and the second bottom electrode collectively provide a multilayered bottom electrode structure having a serpentine pattern.

FIG. 22 is a cross sectional view of the exemplary structure of FIG. 21 after forming a third ILD layer on the second ILD layer to provide a multi-layered ILD containing region.

FIG. 23 is a cross sectional view of the exemplary structure of FIG. 22 after performing the processing steps of FIGS. 11-17.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

For high performance MRAM devices based on perpendicular MTJ-containing pillars, well-defined interfaces and interface control are essential. Embedded MTJ-containing pillars are usually formed by patterning a blanket MTJ-containing stack utilizing one of reactive ion etching (RIE) and ion beam etching (IBE). Processing the blanket MTJ-containing stack into a MTJ-containing pillar utilizing RIE and IBE presents a major challenge as it leads to shorts caused by re-sputtered bottom electrode metal particles on the sidewall of the MTJ-containing pillar. A memory device which is devoid of re-sputtered bottom electrode metal particles on the sidewall of the MTJ-containing pillar is desired.

Referring first to FIG. 1, there is illustrated an exemplary structure that can be employed in the present application, the exemplary structure including a first electrically conductive structure 14 embedded in a first ILD layer 10, and a dielectric cap 16 located on the first ILD layer 10 and the first electrically conductive structure 14. In some embodiments and as is illustrated in FIG. 1, a first diffusion barrier liner 12 can be present along a sidewall and a bottom surface of the first electrically conductive structure 14. In other embodiments, the first diffusion barrier liner 12 can be omitted. Collectively, the first electrically conductive structure 14, the optional first diffusion barrier liner 12 and the first ILD layer 10 provide a metal (or interconnect) level, Mn, wherein n is any integer starting from 1; the upper limit of ‘n’ can vary and can be predetermined by the manufacturer of a specific integrated circuit. Although FIG. 1 describes and illustrates a single first electrically conductive structure 14 embedded in the first ILD layer 10, the present application contemplates embodiments when more than one first electrically conductive structure 14 is embedded in the first ILD layer 10. When more than one first electrically conductive structure 14 is embedded in the first ILD layer 10, some or all of the first electrically conductive structures can be processed to include a serpentine bottom electrode in accordance with the present application.

In some embodiments, the first electrically conductive structure 14 can extend entirely through the first ILD layer 10. In other embodiments, the first electrically conductive structure 14 extends partially through the first ILD layer 10 and in such embodiments, the first electrically conductive structure 14 can be connected to another electrically conductive structure such as, for example, a metal line and/or a metal via, that can be located directly beneath, and in contact with, the first electrically conductive structure 14.

Although not illustrated in any of the drawings of the present application, a substrate can be located beneath metal level, Mn. The substrate can include a front-end-of the-line (FEOL) level including one or more semiconductor devices, such as, for example, field effect transistors located on a semiconductor material; a middle-of-the-line (MOL) level including a plurality of metal contact structures embedded in a MOL dielectric material layer; at least one lower interconnect level that includes a plurality of lower interconnect structures embedded in a lower interconnect dielectric material layer; or any combination thereof. In one example, the substrate includes a FEOL level and a MOL level.

The metal level, Mn, can be formed utilizing techniques that are known to those skilled in the art. In one embodiment, a damascene process can be used in forming metal level, Mn. A damascene process can include forming an opening into the first ILD layer 10, filling the opening with an optional diffusion barrier layer, and an electrically conductive material and, if needed performing a planarization process such as, for example, chemical mechanical polishing (CMP) to remove the optional diffusion barrier layer and the electrically conductive material from the topmost surface of the first ILD layer 10. The diffusion barrier layer that remains in the opening can be referred to herein as the first diffusion barrier liner 12, and the electrically conductive material that remains in the opening can be referred to herein as the first electrically conductive structure 14. In some embodiments, and as shown in FIG. 1, the first electrically conductive structure 14 has a topmost surface that is substantially coplanar with a topmost surface of the first ILD layer 10 as well as with a topmost surface of the first diffusion barrier liner 12, if the same is present.

The first ILD layer 10 can be composed of a dielectric material such as, for example, silicon dioxide, silicon nitride, undoped silicate glass (USG), fluorosilicate glass (FSG), borophosphosilicate glass (BPSG), a spin-on low-k dielectric material, a chemical vapor deposition (CVD) low-k dielectric material or any combination thereof. The term “low-k” as used throughout the present application denotes a dielectric material that has a dielectric constant of less than 4.0. All dielectric constants mentioned herein as measured in a vacuum unless otherwise noted. Illustrative low-k dielectric materials that can be used as the first ILD layer 10 include, but are not limited to, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. Although not shown, the first ILD layer 10 can include a multilayered structure that includes at least two different dielectric materials stacked one atop the other. The first ILD layer 10 can be formed utilizing a deposition process including, for example, chemical vapor deposition (CVD), plasma enhanced chemical vapor deposition (PECVD), evaporation or spin-on coating.

The diffusion barrier layer (and thus the first diffusion barrier liner 12) that can optionally be employed in the present application includes a diffusion barrier material (i.e., a material that serves as a barrier to prevent a conductive material such as copper from diffusing there through). Examples of diffusion barrier materials that can be used in providing the diffusion barrier layer (and thus the first diffusion barrier liner 12) include, but are not limited to, Ta, TaN, Ti, TiN, Ru, RuN, RuTa, RuTaN, W, or WN; in some instances of the present application chemical symbols, as found in the Periodic Table of Elements, are used instead of the full names of the elements or compounds. In some embodiments, the diffusion barrier material can include a material stack of diffusion barrier materials. In one example, the diffusion barrier material can be composed of a stack of Ta/TaN. The diffusion barrier layer can be formed by a deposition process such as, for example, CVD, PECVD, or physical vapor deposition (PVD).

The electrically conductive material that provides the first electrically conductive structure 14 can include an electrically conductive metal and/or an electrically conductive material alloy. Illustrative examples of electrically conductive metals include, but are not limited to, Cu, W, Al, Co, or Ru. An illustrative example of an electrically conductive metal alloy includes Cu—Al alloy. The electrically conductive material that provides first electrically conductive structure 14 can be formed by a deposition process such as, for example, CVD, PECVD, PVD, sputtering or electroplating. In some embodiments, a reflow anneal can follow the deposition of the electrically conductive material that provides first electrically conductive structure 14.

After forming the metal level, Mn, dielectric cap 16 is formed. Dielectric cap 16 is composed of a dielectric capping material which is compositionally different from the dielectric material that provides the first ILD layer 10. The dielectric capping material that provides the dielectric cap 16 can include, but is not limited to, silicon nitride (SiN), or a dielectric containing atoms of silicon, nitrogen and carbon (i.e., SiNC). The dielectric cap 16 can be formed by a deposition process including, but not limited to, atomic layer deposition (ALD), CVD, PECVD or PVD.

Referring now to FIG. 2, there is illustrated the exemplary structure of FIG. 1 after patterning the dielectric cap 16 to physically expose the first electrically conductive structure 14 and forming a metal cap 18 on the physically exposed first electrically conductive structure 14 and adjacent to the patterned dielectric cap 16. The patterning of the dielectric cap 16 includes lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In the present application, the patterning of the dielectric cap 16 forms an opening in the dielectric cap 16 that physically exposes the first electrically conductive structure 14. In some embodiments, the opening can also physically expose a topmost surface of the first diffusion barrier liner 12, if the first diffusion barrier liner 12 is present. In other embodiments (not shown), the opening formed in the dielectric cap 16 does not physically expose the first diffusion barrier liner 12.

The metal cap 18 is composed of a metal that is inert as compared to the electrically conductive material present in the electrically conductive structure 14. Illustrative examples of such inert metals include, but are not limited to, Ta, W or Ru. The metal cap 18 can be formed in the opening formed in the dielectric cap 16 by a deposition process, followed by planarization including CMP. The deposition process used in forming the metal cap 18 can include, for example, CVD, PECVD, PVD, sputtering or electroplating. The metal cap 18 has a topmost surface that is substantially coplanar with a topmost surface of the patterned dielectric cap 16.

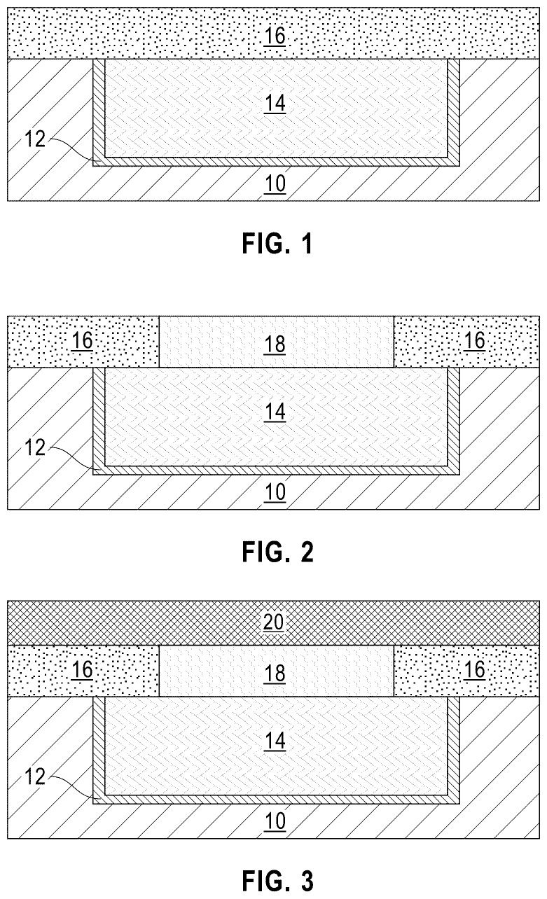

Referring now to FIG. 3, there is illustrated the exemplary structure of FIG. 2 after forming a second ILD layer 20 on the patterned dielectric cap 16 and the metal cap 18. The second ILD layer 20 can include a dielectric material as mentioned above for the first ILD layer 10. The dielectric material that provides the second ILD layer 20 can be compositionally the same as, or compositionally different from, the dielectric material that provides the first ILD layer 10. The dielectric material that provides the second ILD layer 20 is however compositionally different from the dielectric capping material that provides the dielectric cap 16. The second ILD layer 20 can be formed by a deposition process such as, for example, CVD, PECVD, evaporation or spin-on coating. A planarization process such as, for example, CMP, can follow the deposition of the dielectric material that provides the second ILD layer 20.

Referring now to FIG. 4, there is illustrated the exemplary structure of FIG. 3 after forming a first patterned hard mask 24 on the second ILD layer 20. In some embodiments, the first patterned hard mask 24 includes a plurality of openings formed therein. In another embodiment, a single opening can be present in the first patterned hard mask 24. The first patterned hard mask 24 is composed of a dielectric hard mask material include, for example, silicon dioxide, silicon nitride and/or silicon oxynitride. The first patterned hard mask 24 can be formed by deposition of a blanket layer of hard mask material, followed by lithographic patterning in which the transfer etch is selective in removing the dielectric hard mask material. The deposition of the blanket layer of hard mask material includes, but is not limited to, CVD, PECVD or PVD.

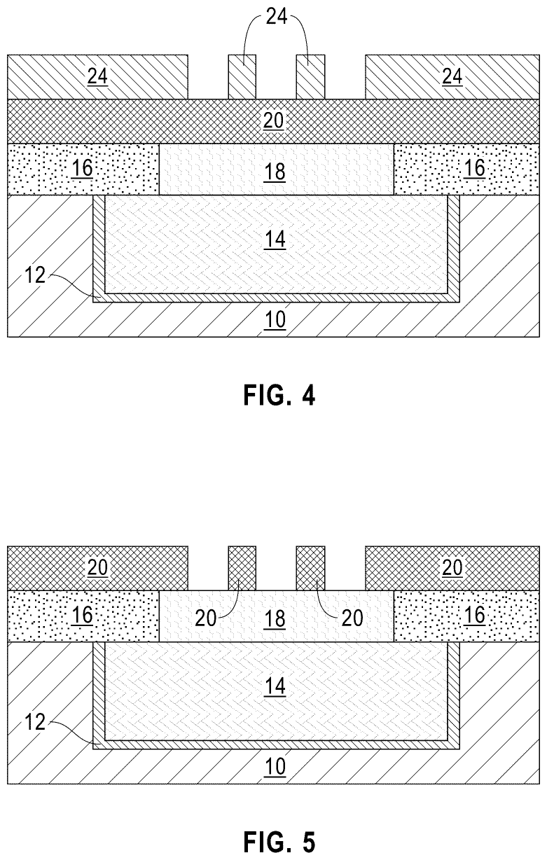

Referring now to FIG. 5, there is illustrated the exemplary structure of FIG. 4 after performing an etch to transfer the pattern provided by the first patterned hard mask 24 into the second ILD layer 20, and removing the first patterned hard mask 24. The etch to transfer the pattern provided by the first patterned hard mask 24 into the second ILD layer 20 is selective in removing the second ILD layer 20 that is not protected by the first patterned hard mask 24. The etch used in the pattern transfer step stops on a surface of the metal cap 18. The first patterned hard mask 24 is removed after performing the pattern transfer etch by a material removal process that is selective in removing the first patterned hard mask 24. After the pattern transfer etch, the second ILD layer 20 is patterned to include at least one opening therein. Each opening in the second ILD layer 20 physically exposes a portion of the metal cap 18. The at least one opening in the second ILD layer 20 will be used in forming a bottom electrode that has a serpentine pattern. The term “serpentine pattern” is used throughout the present application to denote a meandering pattern that includes at least one hill and at least one valley.

Referring now to FIG. 6, there is illustrated the exemplary structure of FIG. 5 after forming a bottom electrode material containing layer 26L having a serpentine pattern on the second ILD layer 20 that was previously patterned. The bottom electrode material containing layer 26L is composed of a conductive metal-containing material such as, for example, Ta, TaN, Ti, TiN, Ru, RuN, RuTa, RuTaN, W, or WN. The bottom electrode material containing layer 26L can be formed by deposition of a conductive metal-containing material. The deposition of the conductive metal-containing material can include, but is not limited to, CVD, PECVD, ALD, or sputtering. In some embodiments, the bottom electrode material containing layer 26L is a conformal layer. As used herein, the term “conformal layer” denotes that a material layer has a vertical thickness along horizontal surfaces that is substantially the same (i.e., within ±5%) as the lateral thickness along vertical surfaces.

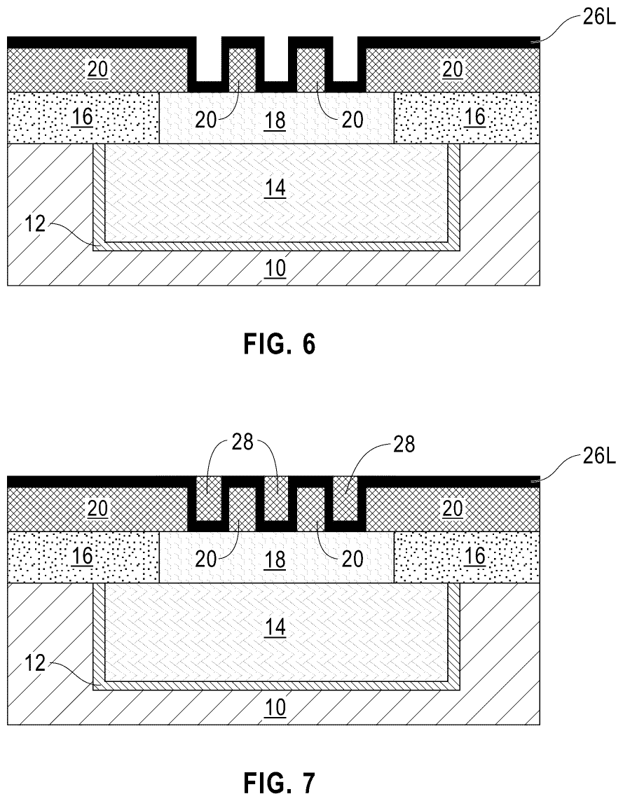

Referring now to FIG. 7, there is illustrated the exemplary structure of FIG. 6 after forming a gap filling ILD layer 28 in the gaps (or single gap) provided by the serpentine pattern of the bottom electrode containing layer 26L. The gap filling ILD layer 28 is composed of a dielectric material as mentioned above for the first ILD layer 10. The dielectric material that provides the gap filling ILD layer 28 can be compositionally the same as, or compositionally different from, the dielectric material that provides the first ILD layer 10 and/or second ILD layer 20. The gap filling ILD layer 28 can be formed by a deposition process such as, for example, CVD, PECVD, evaporation or spin-on coating. A planarization process such as, for example, CMP, can follow the deposition of the dielectric material that provides the gap filling ILD layer 28.

Referring now to FIG. 8, there is illustrated the exemplary structure of FIG. 7 after forming a second patterned hard mask 30 on a portion of the bottom electrode containing layer 26L and on the gap filling ILD layer 28 that is located in the gaps provided by the serpentine pattern of the bottom electrode containing layer 26L. It is noted that the second patterned hard mask 30 is formed directly over the serpentine pattern that is present in the bottom electrode containing layer 26L. The second patterned hard mask 30 is composed of a dielectric hard mask material include, for example, silicon dioxide, silicon nitride and/or silicon oxynitride. The second patterned hard mask 30 can be formed by deposition of a blanket layer of hard mask material, followed by lithographic patterning in which the transfer etch is selective in removing the dielectric hard mask material. The deposition of the blanket layer of hard mask material includes, but is not limited to, CVD, PECVD or PVD.

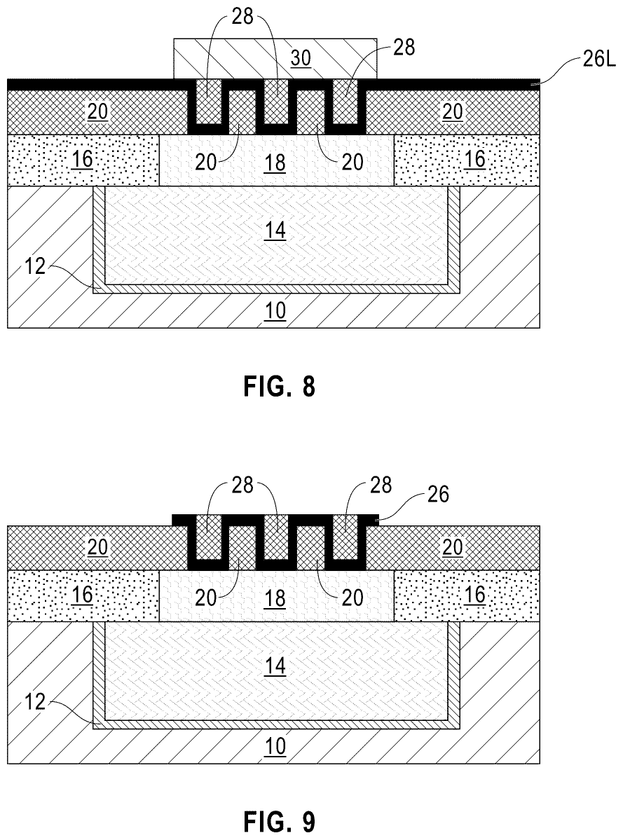

Referring now to FIG. 9, there is illustrated the exemplary structure of FIG. 8 after removing physically exposed portions of the bottom electrode containing layer 26L that are not protected by the second patterned hard mask 30, and removing the second patterned hard mask 30 to reveal a bottom electrode 26 having a serpentine pattern in which the gaps provided by the serpentine pattern are filled with the gap filling ILD layer 28. The physically exposed portions of the bottom electrode containing layer 26L are removed utilizing an etching process that is selective in removing the bottom electrode containing layer 26L that is not protected by the second patterned hard mask 30. After removing the physically exposed portions of the bottom electrode containing layer 26L that are not protected by the second patterned hard mask 30, the second patterned hard mask 30 is removed utilizing a material removal process that is selective in removing the second patterned hard mask 30. As is shown in FIG. 9, bottom electrode 26 has a topmost surface (represented by each ‘hill’ portion of the bottom electrode 26) that is substantially coplanar with a topmost surface of the gap filling ILD layer 28. The bottommost surface (represented by each “valley” portion of the bottom electrode 26) is in electrical contact with the metal cap 18.

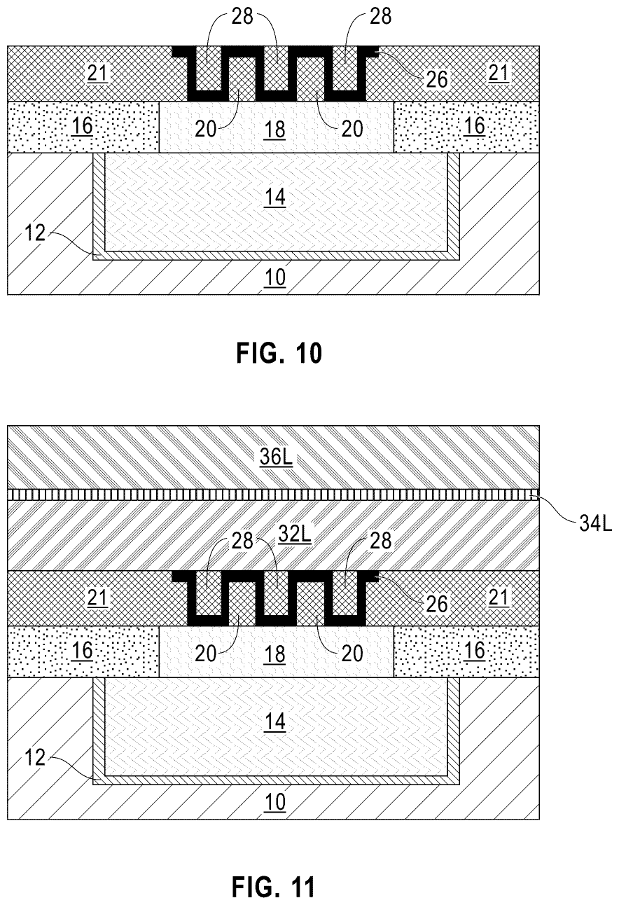

Referring now to FIG. 10, there is illustrated the exemplary structure of FIG. 9 after forming a third ILD layer (not separately shown or labeled in FIG. 10) on the second ILD layer 20 to provide a multi-layered ILD containing region 21. The multi-layered ILD containing region 21 includes a combination of the third ILD layer and the second ILD layer 20. The third ILD layer is composed of a dielectric material as mentioned above for the first ILD layer 10. The dielectric material that provides the third ILD layer can be compositionally the same as, or compositionally different from, the dielectric material that provides the first ILD layer 10 and/or second ILD layer 20 and/or the gap filling ILD layer 28. The third ILD layer can be formed by a deposition process such as, for example, CVD, PECVD, evaporation or spin-on coating. A planarization process such as, for example, CMP, can follow the deposition of the dielectric material that provides the third ILD layer. As is shown in FIG. 10, the multi-layered ILD containing region 21 has a topmost surface that is substantially coplanar with a topmost surface (represented by each ‘hill’ portion of the bottom electrode 26) of the bottom electrode 26 and a topmost surface of the gap filling ILD layer 28. It is noted that the gap filling ILD layer 28 is located above each ‘valley’ portion of the bottom electrode 26 and the second ILD layer 20 present in the multi-layered ILD containing region 21 is located beneath each ‘hill’ portion of the bottom electrode 26.

Referring now to FIG. 11, there is illustrated the exemplary structure of FIG. 10 after forming a MTJ-containing stack including a blanket bottom magnetic material containing layer 32L, a blanket tunnel barrier layer 34L and a blanket upper magnetic material containing layer 36L. The blanket bottom magnetic material containing layer 32L includes a magnetic pinned (or reference) material or a magnetic free material. The blanket upper magnetic material containing layer 36L includes the other of the magnetic pinned material or magnetic free material not employed in the blanket bottom magnetic material containing layer 32L. In one example, the blanket bottom magnetic material containing layer 32L includes a magnetic pinned (or reference) material, and the blanket upper magnetic material containing layer 36L includes a magnetic free material. In another example, the blanket bottom magnetic material containing layer 32L includes a magnetic free material, and the blanket upper magnetic material containing layer 36L includes a magnetic pinned (or reference) material.

In embodiments in which MTJ-containing stack includes a magnetic pinned (or reference) material as the blanket bottom magnetic material containing layer 32L and a magnetic free material as the blanket upper magnetic material containing layer 36L, the MTJ-containing stack (and the subsequently formed MTJ-containing pillar) can be referred to as a bottom pinned MTJ-containing stack (or bottom pinned MTJ-containing pillar). In embodiments in which MTJ-containing stack includes a magnetic free material as the blanket bottom magnetic material containing layer 32L and a magnetic pinned (or reference) material as the blanket upper magnetic material containing layer 36L, the MTJ-containing stack (and the subsequently formed MTJ-containing pillar) can be referred to as a top pinned MTJ-containing stack (or top pinned MTJ containing pillar).

In some embodiments, the bottom pinned MTJ-containing stack can also include an optional blanket layer of metal seed material (not shown). In the bottom pinned MTJ-containing material stack, the optional blanket layer of metal seed material is formed directly beneath the blanket bottom magnetic material containing layer 32L. In some embodiments, the top pinned MTJ-containing stack can also include an optional blanket layer of metal seed material (not shown). In the top pinned MTJ-containing material stack, the optional blanket layer of metal seed material is formed directly beneath the blanket upper magnetic material containing layer 36L. In some embodiments, the MTJ-containing stack can also include a blanket layer of MTJ cap material (not shown) located on the blanket upper magnetic material containing layer 36L. In some embodiments, the magnetic free material can be composed of a single magnetic free material or a multilayered stack of magnetic free materials. In some embodiments, the magnetic free material includes a non-magnetic spacer material located between a first magnetic free material and a second magnetic free material.

The magnetic pinned material has a fixed magnetization. The magnetic pinned material can be composed of a metal or metal alloy (or a stack thereof) that includes one or more metals exhibiting high spin polarization. In alternative embodiments, exemplary metals for the formation of the magnetic pinned material include iron, nickel, cobalt, chromium, boron, or manganese. Exemplary metal alloys can include the metals exemplified by the above. In another embodiment, the magnetic pinned material can be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that can be used include a metal such as cobalt, nickel, platinum, palladium, iridium, or ruthenium, and can be arranged as alternating layers. The strong PMA region can also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys can be arranged as alternating layers. In one embodiment, combinations of these materials and regions can also be employed as the magnetic pinned material.

The blanket tunnel barrier layer 34L is composed of an insulator material and is formed at such a thickness as to provide an appropriate tunneling resistance. Exemplary materials for the blanket tunnel barrier layer 34L include magnesium oxide, aluminum oxide, and titanium oxide, or materials of higher electrical tunnel conductance, such as semiconductors or low-bandgap insulators.

The magnetic free material can be composed of a magnetic material (or a stack of magnetic materials) with a magnetization that can be changed in orientation relative to the magnetization orientation of the magnetic pinned layer. It is noted that the term “magnetic free material” denotes that the magnetic material does not have a fixed magnetization as is the case with magnetic pinned materials, but instead it is free to rotate upon application of an applied voltage. Exemplary magnetic materials for the magnetic free material include alloys and/or multilayers of cobalt, iron, alloys of cobalt-iron, nickel, alloys of nickel-iron, and alloys of cobalt-iron-boron.

If present, the non-magnetic metallic spacer material is composed of a non-magnetic metal or metal alloy that allows magnetic information to be transferred therethrough and also permits the two magnetic free layers to couple together magnetically, so that in equilibrium the first and second magnetic free layers are always parallel. The non-magnetic metallic spacer material allows for spin torque switching between a first magnetic free material and a second magnetic free material. The first magnetic free material and the second magnetic free material can include one of the magnetic free materials mentioned. The first magnetic free material can be compositionally the same as, or compositionally different from, the second magnetic free material.

The optional blanket layer of metal seed material can be composed of Pt, Pd, Ni, Rh, Ir, Re or alloys and multilayers thereof. In one example, the optional blanket layer of metal seed material is composed of Pt. If present, the blanket layer of MTJ cap material can be composed of Nb, NbN, W, WN, Ta, TaN, Ti, TiN, Ru, Mo, Cr, V, Pd, Pt, Rh, Sc, Al or other high melting point metals or conductive metal nitrides.

The MTJ-containing stack can be formed by utilizing one or more deposition processes such as, for example, sputtering, plasma enhanced atomic layer deposition (PEALD), PECVD or PVD.

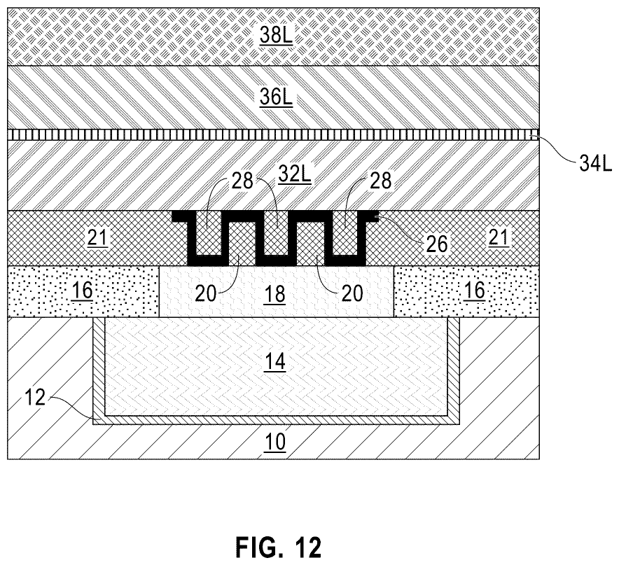

Referring now to FIG. 12, there is illustrated the exemplary structure of FIG. 11 after forming a top electrode material containing layer 38L on the MTJ-containing stack. The top electrode material containing layer 38L is composed of a conductive metal-containing material such as, for example, Ta, TaN, Ti, TiN, Ru, RuN, RuTa, RuTaN, W, or WN. The conductive metal-containing material that provides the top electrode material containing layer 38L can be compositionally the same as, or compositionally different from, the conductive metal-containing material that provides the top electrode material containing layer 26L. The top electrode material containing layer 38L can be formed by deposition of a conductive metal-containing material. The deposition of the conductive metal-containing material can include, but is not limited to, CVD, PECVD, ALD, or sputtering.

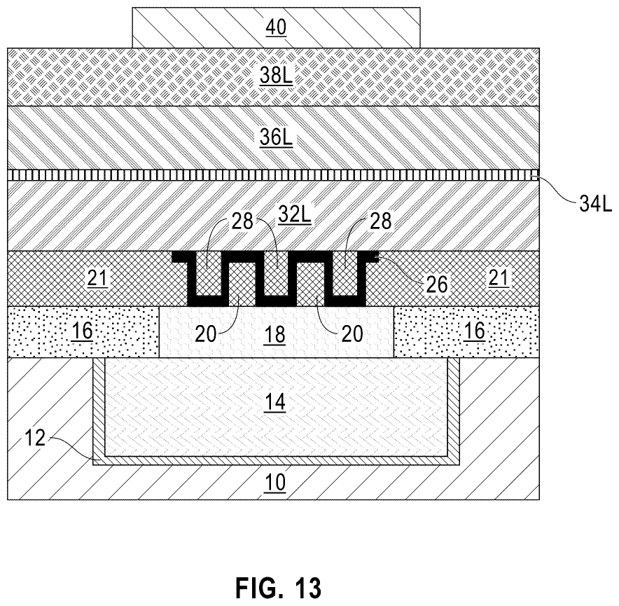

Referring now to FIG. 13, there is illustrated the exemplary structure of FIG. 12 after forming a third patterned hard mask 40 on the top electrode material containing layer 38L. The third patterned hard mask 40 is formed on the top electrode material containing layer 38L and above the MTJ-containing stack that is located above the bottom electrode 26. The third patterned hard mask 40 is designed to have a width that extends beyond the outermost sidewall of the bottom electrode 26. The third patterned hard mask 40 is composed of a dielectric hard mask material include, for example, silicon dioxide, silicon nitride and/or silicon oxynitride. The third patterned hard mask 40 can be formed by deposition of a blanket layer of hard mask material, followed by lithographic patterning in which the transfer etch is selective in removing the dielectric hard mask material. The deposition of the blanket layer of hard mask material includes, but is not limited to, CVD, PECVD or PVD.

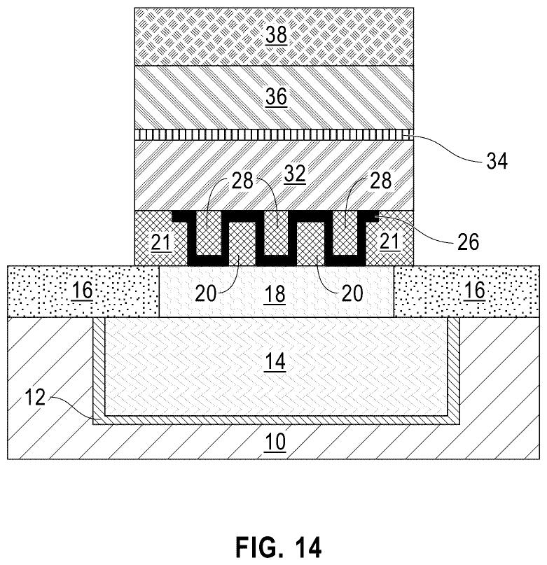

Referring now to FIG. 14, there is illustrated the exemplary structure of FIG. 13 after etching the top electrode material containing layer 38L and the MTJ-containing stack to provide a top electrode 38 and a MTJ-containing pillar respectively, in which the etching utilizes the third patterned hard mask 40 as an etch mask, and removing the third patterned hard mask 40. The etch also patterns the multi-layered ILD containing region 21 as shown in FIG. 14. The etch can include RIE or IBE. It is noted that since the bottom electrode 26 is embedded in the multi-layered ILD containing region 21 and since the third patterned hard mask 40 is designed to have a width that extends beyond the outermost sidewall of the bottom electrode 26, the bottom electrode 26 is not etched and thus no re-sputtering of bottom electrode metal particles on the sidewall of the MTJ-containing pillar occurs. As a result of avoiding the re-sputtering of bottom electrode metal particles on the sidewall of the MTJ-containing pillar, no shorts of the resultant memory device is observed. The MTJ-containing pillar includes an un-etched portion of at least each of the blanket bottom magnetic material containing layer 32L, the blanket tunnel barrier layer 34L and the blanket upper magnetic material containing layer 36L. The un-etched portion of the blanket bottom magnetic material containing layer 32L can be referred to herein as a bottom magnetic material containing layer 32, the un-etched portion of the blanket tunnel barrier layer 34L can be referred to herein as a tunnel barrier layer 34, and the unetched portion of the blanket upper magnetic material containing layer 36L can be referred herein as an upper magnetic material containing layer 36.

After etching, the third patterned hard mask 40 is removed from on top of the top electrode 38 utilizing a material removal process that is selective in removing the third patterned hard mask 40 from the exemplary structure.

As is shown in FIG. 14, the top electrode 38 has a sidewall that is vertically aligned to a sidewall of the MTJ-containing pillar (including a sidewall of each of the bottom magnetic material containing layer 32, the tunnel barrier layer 34, and the upper magnetic material containing layer 36). The vertically aligned sidewalls of the top electrode 38 and the MTJ-containing pillar extend beyond the outermost sidewall of the bottom electrode 26. The vertically aligned sidewalls of the top electrode 38 and the MTJ-containing pillar are also vertically aligned to a sidewall of the remaining multi-layered ILD containing region 21. In some embodiments, the etch can form a stack of the top electrode 28 and the MTJ-containing pillar in which the sidewalls slightly taper inward or outward from the top electrode 28 to the bottommost layer of the MTJ-containing pillar.

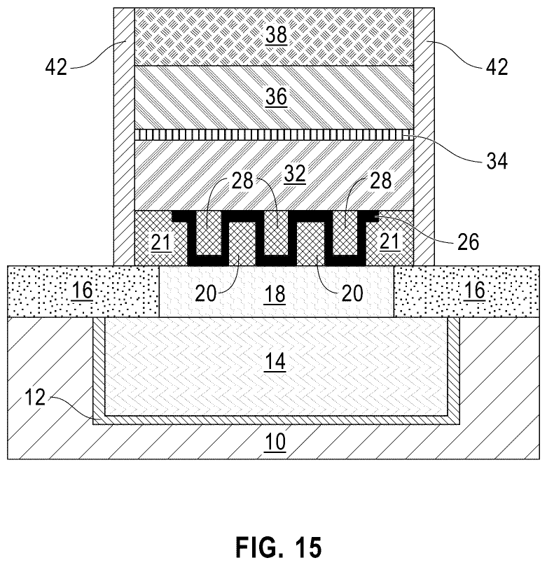

Referring now to FIG. 15, there is illustrated the exemplary structure of FIG. 14 after forming an encapsulation liner 42 on sidewalls of the top electrode 38, the MTJ-containing pillar, and the remaining, i.e., patterned, multi-layered ILD containing region 21. The encapsulation liner 42 is composed of an encapsulation dielectric material that can provide passivation to the MTJ-containing pillar. In some embodiments, the encapsulation dielectric material that provides the encapsulation liner 42 can be composed of silicon nitride. In other embodiments, the encapsulation dielectric material that provides the encapsulation liner 42 contains atoms of silicon, carbon and hydrogen. In some embodiments, and in addition to atoms of carbon and hydrogen, the encapsulation dielectric material that provides the encapsulation liner 42 can include atoms of at least one of nitrogen and oxygen. In other embodiments, and in addition to atoms of silicon, nitrogen, carbon and hydrogen, the encapsulation dielectric material that provides the encapsulation liner 42 can include atoms of boron. In one example, the encapsulation dielectric material that provides the encapsulation liner 42 can be composed of an SiNC dielectric material that can contain atoms of silicon, carbon, hydrogen, nitrogen and oxygen. In alternative example, the encapsulation dielectric material that provides the encapsulation liner 42 can be composed of a SiBCN dielectric material that contains atoms of silicon, boron, carbon, hydrogen, and nitrogen.

The encapsulation liner 42 can be formed by depositing a conformal layer of an encapsulation dielectric material on physically exposed surfaces of the top electrode 38, the MTJ-containing pillar, the remaining, i.e., patterned, multi-layered ILD containing region 21, and the dielectric cap 16. The conformal layer of encapsulation dielectric material can be formed by a conformal deposition process, including but not limited to, ALD, CVD, PECVD or PVD. The formation of the encapsulation liner 42 continues by removing the conformal layer of encapsulation dielectric material from all horizonal surfaces of the exemplary structure, while maintaining the conformal layer of encapsulation dielectric material along the sidewalls of the top electrode 38, the MTJ-containing pillar, and the remaining, i.e., patterned, multi-layered ILD containing region 21. The remaining conformal layer of encapsulation dielectric material that is present along the sidewall of the MTJ-containing pillar can be referred to herein as encapsulation liner 42. The encapsulation liner 42 is pillar shaped and laterally surrounds the sidewalls of the top electrode 38, the MTJ-containing pillar, and the remaining, i.e., patterned, multi-layered ILD containing region 21. The removal of the conformal layer of encapsulation dielectric material from all horizonal surfaces can include a dielectric etch back process. As is illustrated in FIG. 15, the encapsulation liner 42 is located on a sidewall of each of the bottom magnetic material containing layer 32, the tunnel barrier layer 34 and the upper magnetic material containing layer 36. The encapsulation liner 42 has a bottommost surface that is in direct physical contact with a topmost surface of the dielectric cap 16, and a topmost surface that is substantially coplanar with a topmost surface of the top electrode 38.

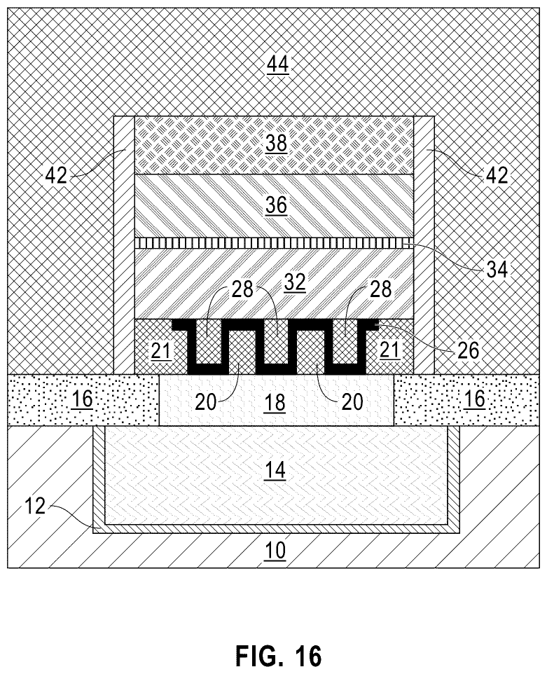

Referring now to FIG. 16, there is illustrated the exemplary structure of FIG. 15 after forming a fourth ILD layer 44 adjacent to the encapsulation liner 42 and on top of the top electrode 38. The fourth ILD layer 44 can include a dielectric material as mentioned above for the first ILD layer 10. The dielectric material that provides the fourth ILD layer 44 can be compositionally the same as, or compositionally different from, the dielectric material that provides the first ILD layer 10 and/or the second ILD layer 20 and/or the third ILD layer. The fourth ILD layer 44 can be formed by a deposition process such as, for example, CVD, PECVD, evaporation or spin-on coating. A planarization process such as, for example, CMP, can follow the deposition of the dielectric material that provides the fourth ILD layer 44.

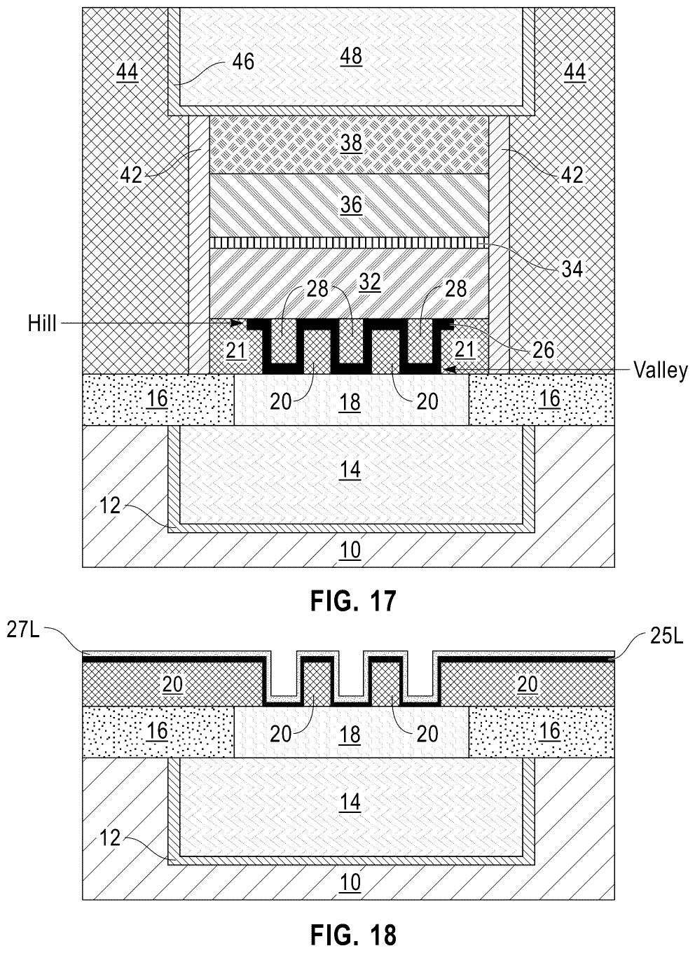

Referring now to FIG. 17, there is illustrated the exemplary structure of FIG. 16 after forming a second electrically conductive structure 48 in the fourth ILD layer 44 and in electrical contact with the top electrode 38. An optional second diffusion barrier liner 46 can be present along a sidewall and a bottom surface of the second electrically conductive structure 48. The second electrically conductive structure 48 is composed of electrically conductive material as mentioned above for the first electrically conductive structure 14. The optional second diffusion barrier liner 46 is composed of a diffusion barrier material as mentioned above for the optional first diffusion barrier liner 12. The optional second diffusion barrier liner 46 and the second electrically conductive structure 48 can be formed by a damascene process as mentioned above in forming the optional first diffusion barrier liner 12 and the first electrically conductive structure 14. In this embodiment, the second electrically conductive structure 48 is electrically connected (either directly or indirectly) to the top electrode 38. Also and in this embodiment, the bottom electrode 26 is electrically connected to both the first electrically conductive structure 14 (via the metal cap 18) and to the MTJ-containing pillar. The bottom electrode 26 having the serpentine pattern has a reduced contact area with the MTJ-containing pillar as compared to a entirely planer bottom electrode that is typically used in the prior art. Despite having the reduced contact area, the bottom electrode 26 having the serpentine pattern has a smoother topmost surface than an entirely planar bottom electrode that is typically used in the prior art. The smoother surface provides for an enhanced interface between the bottom electrode 26 and the MTJ-containing pillar.

Notably, FIG. 17 illustrates an exemplary memory device in accordance with an embodiment of the present application. The memory device illustrated in FIG. 17 includes first electrically conductive structure 14, metal cap 18 located on the first electrically conductive structure 14, MTJ-containing pillar located above the metal cap 18, bottom electrode 26 having a serpentine pattern located between the metal cap 18 and the MTJ-containing pillar in which the bottom electrode 26 has a bottommost surface in contact with the metal cap 18 and a topmost surface in contact with the MTJ-containing pillar, top electrode 38 located on the MTJ-containing pillar, and second electrically conductive structure 48 electrically connected to the top electrode 38. The presence of the bottom electrode 26 having a serpentine pattern enables improved magnetic performance of the memory device by providing a bottom electrode top surface which has reduced surface roughness or surface undulations by virtue of the reduced metal content in the bottom electrode topmost surface interfacing with the bottommost surface of the MTJ-containing pillar.

In some embodiments, the MTJ-containing pillar illustrated in FIG. 17 includes bottom magnetic material containing layer 32, tunnel barrier layer 34 and upper magnetic material containing layer 36 in which the bottom magnetic material containing layer 32 includes a magnetic free material, and the upper magnetic material containing layer 36 includes a magnetic reference material. Such an MTJ-containing pillar is referred to a top pinned MTJ-containing pillar.

In some embodiments, the MTJ-containing pillar illustrated in FIG. 17 includes bottom magnetic material containing layer 32, tunnel barrier layer 34 and upper magnetic material containing layer 36 in which the bottom magnetic material containing layer 32 includes a magnetic reference material, and the upper magnetic material containing layer 36 includes a magnetic free material. Such an MTJ-containing pillar is referred to a bottom pinned MTJ-containing pillar.

In some embodiments of the present application, the top electrode 38 and the MTJ-containing pillar of the memory device illustrated in FIG. 17 are laterally surrounded by encapsulation liner 42. The encapsulation liner 42 can provide protection (i.e., electrically isolation) to the top electrode 38 and the MTJ-containing pillar and, in some embodiments, passivates the MTJ-containing pillar.

In some embodiments of the present application, the memory device of FIG. 17 further includes multi-layered ILD containing region 21 located adjacent to, and embedding, the bottom electrode 26. This aspect of the present application in which the bottom electrode 26 is embedded in the multi-layered ILD containing region 21 prevents bottom electrode metal particles from re-sputtering on the sidewall of the MTJ-containing pillar during formation of the same. Thus, it aids in preventing possible shorting of the memory device.

In some embodiments of the present application, the memory device of FIG. 17 further includes gap filling ILD layer 28 located in each gap created by the serpentine pattern of the bottom electrode 26. The presence of the gap filling ILD layer 28 provides a surface is which the MTJ-containing pillar can be formed.

In some embodiments, the MTJ-containing pillar illustrated in FIG. 17 has a sidewall that is vertically aligned with a sidewall of the top electrode 38, and the vertically aligned sidewalls of the MTJ-containing pillar and the top electrode 38 extend beyond an outermost sidewall of the bottom electrode 26. This aspect of the present application facilitates the formation of MTJ-containing pillars that are devoid of re-sputtering bottom electrode particles.

In some embodiments, the bottom electrode 26 shown in FIG. 17 having the serpentine pattern includes multiple hills and valleys, in which each hill is in electrical contact with the MTJ-containing pillar, and each valley is in electrical contact with the metal cap 18.

In some embodiments, the bottom electrode 26 shown in FIG. 17 having the serpentine pattern includes a single hill and a single valley, wherein the single hill is in electrical contact with the MTJ-containing pillar, and the single valley is in electrical contact with the metal cap 18.

The bottom electrode 26 having hills and valleys (or single hill and valley) provides a reduced contact area with the MTJ-containing pillar as compared to an entirely planer bottom electrode that is typically used in the prior art. Despite having the reduced contact area, the bottom electrode 26 has a smoother topmost surface than an entirely planer bottom electrode that is typically used in the prior art. The smoother surface provides for an enhanced interface between the bottom electrode 26 and the MTJ-containing pillar.

In some embodiments, the memory device of FIG. 17 further includes a diffusion barrier liner (i.e., second diffusion barrier liner 46) located on a sidewall and a bottom surface of the second electrically conductive structure 48.

Referring now to FIG. 18, there is illustrated the exemplary structure of FIG. 5 after forming a first bottom electrode material containing layer 25L having a serpentine pattern on the second ILD layer 20 that was previously patterned, and a second bottom electrode material containing layer 27L having a serpentine pattern on the first bottom electrode material containing layer 25L. Although not shown, one or more additional bottom electrode material containing layers having a serpentine pattern can be formed on top of the second bottom electrode containing layer 27L. Thus, this embodiment of the present application contemplates forming multiple (2 or greater) bottom electrode material containing layers each having a serpentine pattern.

The first bottom electrode material containing layer 25L is composed of a first conductive metal-containing material, while the second bottom electrode containing layer 27L is composed of a second conductive metal-containing material that is compositionally different from the first conductive metal-containing material. When additional bottom electrode material containing layers are formed, the first additional bottom electrode material containing layer that is formed on the second bottom electrode containing layer 27L is composed of a conductive metal-containing material that is compositionally different from the second conductive metal-containing material that provides the second bottom electrode containing layer 27L, and each successive additional bottom electrode containing layer is composed of a conductive metal-containing material that is compositionally different from the preceding additional bottom electrode containing layer. The conductive metal-containing material (including the first and second conductive metal-containing materials mentioned above) include, for example, Ta, TaN, Ti, TiN, Ru, RuN, RuTa, RuTaN, W, or WN.

The various bottom electrode containing layers (including the first bottom electrode containing layer 25L and the second bottom electrode containing layer 27L) can be formed by a deposition process such as, for example, CVD, PECVD, ALD, or sputtering. It is noted that the various bottom electrode containing layers (including the first bottom electrode containing layer 25L and the second bottom electrode containing layer 27L) can be formed utilizing a same, or a different, deposition process.

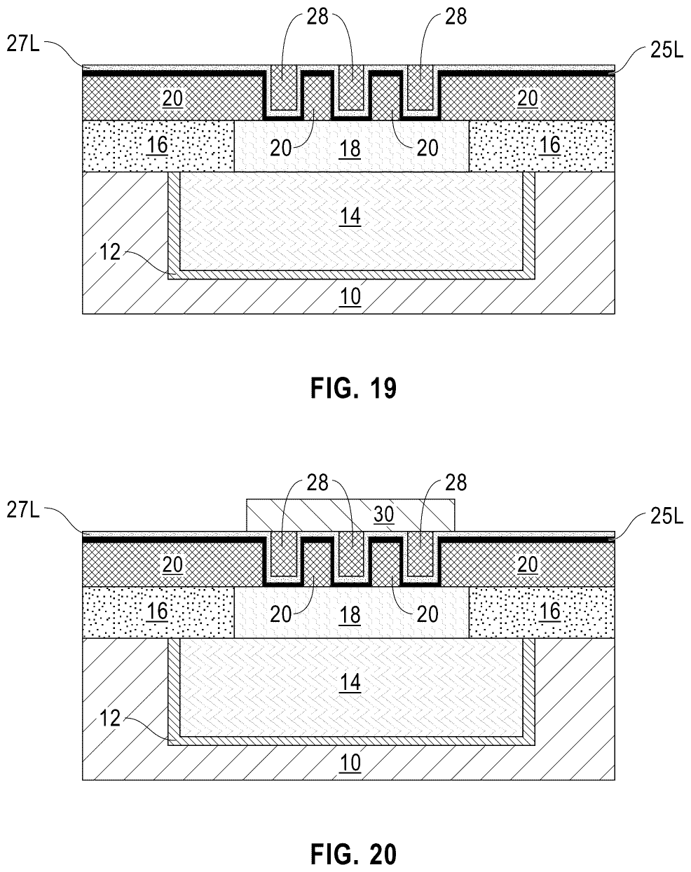

Referring now to FIG. 19, there is illustrated the exemplary structure of FIG. 18 after forming a gap filling ILD layer 28 in the gaps provided by the serpentine pattern of the second bottom electrode containing layer 27L (in embodiments in which more than two bottom electrode material containing layers are formed, the gap filling ILD layer 28 is formed in the gaps provided by the serpentine pattern of the topmost bottom electrode containing layer that is formed). The gap filling ILD layer 28 of this embodiment is the same as the gap filling ILD layer 28 described above in respect to providing the gap filling ILD layer 28 to the exemplary structure shown in FIG. 7. Thus, the description of the gap filling ILD layer 28 provided in respect to FIG. 7 applies here for FIG. 19.

Referring now to FIG. 20, there is illustrated the exemplary structure of FIG. 19 after forming a second patterned hard mask 30 on a portion of the second bottom electrode containing layer 27L (or topmost bottom electrode containing layer) and on the gap filling ILD layer 28 that is located in the gaps provided by the serpentine pattern of the second bottom electrode containing layer 27A (or topmost bottom electrode containing layer). The second patterned hard mask 30 of this embodiment is the same as the second patterned hard mask 30 described above in respect to providing the second patterned hard mask 30 to the exemplary structure shown in FIG. 8. Thus, the description of the second patterned hard mask 30 provided in respect to FIG. 8 applies here for FIG. 20.

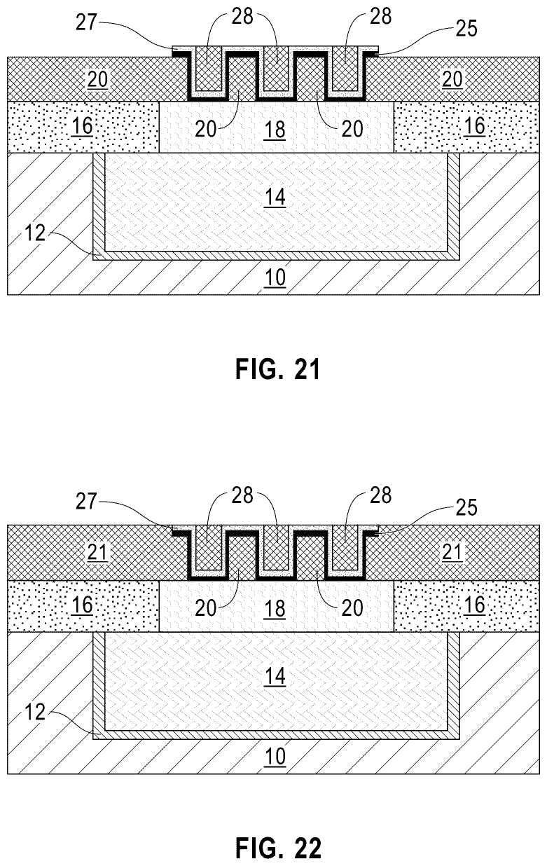

Referring now to FIG. 21, there is illustrated the exemplary structure of FIG. 20 after removing physically exposed portions of the second bottom electrode containing layer 27A and underlying portions of the first bottom electrode containing layer 25A that are not protected by the second patterned hard mask 30, and removing the second patterned hard mask 30 to reveal a second bottom electrode 27 having a serpentine pattern in which the gaps provided by the serpentine pattern are filled with the gap filling ILD layer 28, and a first bottom electrode 25 having a serpentine pattern located beneath the second bottom electrode 27; the first bottom electrode 25 and the second bottom electrode 27 collectively provide a multilayered bottom electrode structure having a serpentine pattern. In the illustrated embodiment, the multilayered bottom electrode structure includes the first bottom electrode 25 and the second bottom electrode 27. In other embodiments, the multilayered bottom electrode structure can contain three or more bottom electrodes each having a serpentine pattern.

The physically exposed portions of the second electrode containing layer 27L and the first bottom electrode containing layer 25L are removed utilizing one or more etching processes that is/are selective in removing the second electrode containing layer 27L and the first bottom electrode containing layer 25L that are not protected by the second patterned hard mask 30. After removing the physically exposed portions of the second electrode containing layer 27L and the first bottom electrode containing layer 25L that are not protected by the second patterned hard mask 30, the second patterned hard mask 30 is removed utilizing a material removal process that is selective in removing the second patterned hard mask 30. As is shown in FIG. 21, the second bottom electrode 27 has a topmost surface (represented by each ‘hill’ portion of the second bottom electrode 27) that is substantially coplanar with a topmost surface of the gap filling ILD layer 28. The first bottom electrode 25 has a bottommost surface (represented by each ‘valley’ portion of the first bottom electrode 25) that is in electrical contact with the metal cap 18. Note that when more than two bottom electrodes are formed, the topmost bottom electrode of the multilayered bottom electrode structure would have a topmost surface that is substantially coplanar with a topmost surface of the gap filling ILD layer 28.

Referring now to FIG. 22, there is illustrated the exemplary structure of FIG. 21 after forming a third ILD layer (not separately shown or labeled in FIG. 10) on the second ILD layer 20 to provide a multi-layered ILD containing region 21. The multi-layered ILD containing region 21 includes a combination of the third ILD layer and the second ILD layer 20. The third ILD layer is composed of a dielectric material as mentioned above for the first ILD layer 10. The dielectric material that provides the third ILD layer can be compositionally the same as, or compositionally different from, the dielectric material that provides the first ILD layer 10 and/or second ILD layer 20 and/or the gap filling ILD layer 28. The third ILD layer can be formed by a deposition process such as, for example, CVD, PECVD, evaporation or spin-on coating. A planarization process such as, for example, CMP, can follow the deposition of the dielectric material that provides the third ILD layer. As is shown in FIG. 22, the multi-layered ILD containing region 21 has a topmost surface that is substantially coplanar with a topmost surface (represented by each ‘hill’ portion of the second bottom electrode 27) of the second bottom electrode 27 and a topmost surface of the gap filling ILD layer 28. Note that when more than two bottom electrodes are formed, the multi-layered ILD containing region 21 has a topmost surface that is substantially coplanar with a topmost surface of the topmost bottom electrode of the multilayered bottom electrode structure and a topmost surface of the gap filling ILD layer 28.

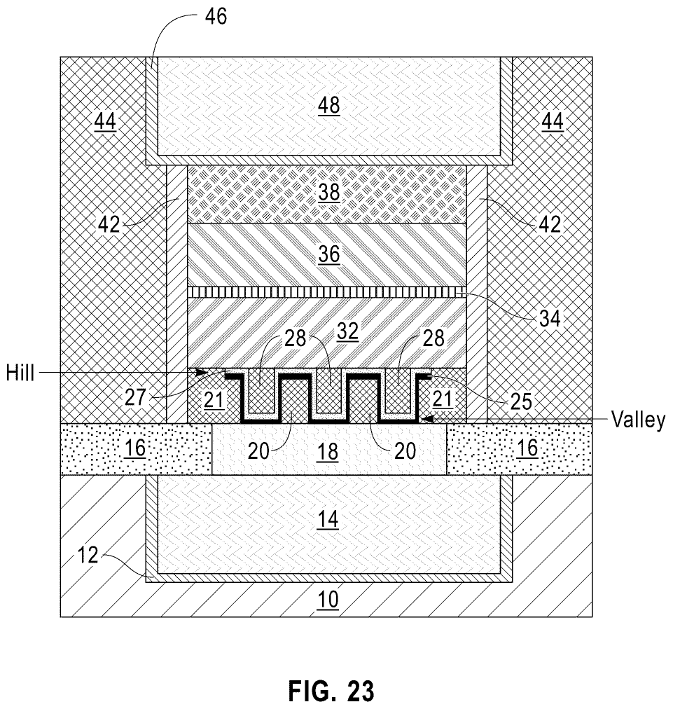

Referring now to FIG. 23, there is illustrated the exemplary structure of FIG. 22 after performing the processing steps of FIGS. 11-17. Notably, FIG. 23 illustrates the exemplary structure of FIG. 22 after forming the MTJ-containing pillar and top electrode 38, encapsulation liner 42, fourth ILD layer 44, the optional second diffusion barrier liner 46 and second electrically conductive structure 48. The MTJ-containing pillar includes at least bottom magnetic material containing layer 32, tunnel barrier layer 34, and upper magnetic material containing layer 36. In this embodiment, the second electrically conductive structure 48 is electrically connected (either directly or indirectly) to the top electrode 38. Also, in this embodiment the first bottom electrode 25 is electrically connected to the first electrically conductive structure 14 (via the metal cap 18) and the topmost bottom electrode (in the illustrated embodiment the topmost bottom electrode is the second bottom electrode 27) of the multilayered bottom electrode structure is electrically connected to the MTJ-containing pillar. The multilayered bottom electrode structure having the serpentine pattern has a reduced contact area with the MTJ-containing pillar as compared to a entirely planer bottom electrode that is typically used in the prior art. Despite having the reduced contact area, the multilayered bottom electrode structure having the serpentine pattern has a smoother topmost surface than the entirely planer bottom electrode that is typically used in the prior art. The smoother surface provides for an enhanced interface between the topmost bottom electrode of the multilayered bottom electrode structure and the MTJ-containing pillar.

Notably, FIG. 23 illustrates an exemplary memory device in accordance with another embodiment of the present application. The memory device illustrated in FIG. 23 includes first electrically conductive structure 14, metal cap 18 located on the first electrically conductive structure 14, MTJ-containing pillar located above the metal cap 18, multilayered bottom electrode structure (e.g., first bottom electrode 25 and second bottom electrode 27) having a serpentine pattern located between the metal cap 18 and the MTJ-containing pillar in which the multilayered bottom electrode structure has a bottommost bottom electrode (i.e., the first bottom electrode 25) in contact with the metal cap 18 and a topmost bottom electrode (e.g., the second bottom electrode 27) in contact with the MTJ-containing pillar, top electrode 38 located on the MTJ-containing pillar, and second electrically conductive structure 48 electrically connected to the top electrode 38. The presence of multilayered bottom electrode structure having a serpentine pattern enables improved magnetic performance of the memory device by providing a bottom electrode top surface which has reduced surface roughness or surface undulations by virtue of the reduced metal content in the bottom electrode topmost surface interfacing with the bottommost surface of the MTJ-containing pillar.

In some embodiments, the MTJ-containing pillar illustrated in FIG. 23 includes bottom magnetic material containing layer 32, tunnel barrier layer 34 and upper magnetic material containing layer 36 in which the bottom magnetic material containing layer 32 includes a magnetic free material, and the upper magnetic material containing layer 36 includes a magnetic reference material. Such an MTJ-containing pillar is referred to a top pinned MTJ-containing pillar.

In some embodiments, the MTJ-containing pillar illustrated in FIG. 23 includes bottom magnetic material containing layer 32, tunnel barrier layer 34 and upper magnetic material containing layer 36 in which the bottom magnetic material containing layer 32 includes a magnetic reference material, and the upper magnetic material containing layer 36 includes a magnetic free material. Such an MTJ-containing pillar is referred to a bottom pinned MTJ-containing pillar.

In some embodiments of the present application, the top electrode 38 and the MTJ-containing pillar of the memory device illustrated in FIG. 23 are laterally surrounded by encapsulation liner 42. The encapsulation liner 42 can provide protection (i.e., electrical isolation) to the top electrode 38 and the MTJ-containing pillar and, in some embodiments, passivates the MTJ-containing pillar.

In some embodiments of the present application, the memory device of FIG. 23 further includes multi-layered ILD containing region 21 located adjacent to, and embedding, the multilayered bottom electrode structure (e.g., first bottom electrode 25 and second bottom electrode 27). This aspect of the present application in which the multilayered bottom electrode structure is embedded in the multi-layered ILD containing region 21 prevents bottom electrode metal particles from re-sputtering on the sidewall of the MTJ-containing pillar during formation of the same. Thus, it aids in preventing possible shorting of the memory device.

In some embodiments of the present application, the memory device of FIG. 23 further includes gap filling ILD layer 28 located in each gap created by the serpentine pattern of the multilayered bottom electrode structure. The presence of the gap filling ILD layer 28 provides a surface on which the MTJ-containing pillar can be formed.

In some embodiments, the MTJ-containing pillar of FIG. 23 has a sidewall that is vertically aligned with a sidewall of the top electrode, and the vertically aligned sidewalls of the MTJ-containing pillar and the top electrode extend beyond an outermost sidewall of the multilayered bottom electrode structure. This aspect of the present application facilitates the formation of MTJ-containing pillars that are devoid of re-sputtering bottom electrode particles.

In some embodiments of the present application, the bottommost bottom electrode (i.e., first bottom electrode 25) includes multiple hills and valleys, in which each valley of the bottommost bottom electrode (i.e., first bottom electrode 25) is in electrical contact with the metal cap 18, and the topmost bottom electrode (e.g., second bottom electrode 27) includes multiple hills and valleys, wherein each hill of the topmost bottom electrode (e.g., second bottom electrode 27) is in electrical contact with the MTJ-containing pillar.

In some embodiments of the present application, the bottommost bottom electrode (i.e., first bottom electrode 25) includes a single hill and a single valley, in which the single valley of the bottommost bottom electrode (i.e., first bottom electrode 25) is in electrical contact with the metal cap 18, and the topmost bottom electrode (e.g., second bottom electrode 27) includes a single hill and a single valley, in which the single hill of the topmost bottom electrode (e.g., second bottom electrode 27) is in electrical contact with the MTJ-containing pillar.

The multilayered bottom electrode structure having hills and valleys (or single hill and valley) provides a reduced contact area with the MTJ-containing pillar as compared to an entirely planar bottom electrode that is typically used in the prior art. Despite having the reduced contact area, the multilayered bottom electrode structure has a smoother topmost surface than an entirely planer bottom electrode that is typically used in the prior art. The smoother surface provides for an enhanced interface between the topmost bottom electrode of the multilayered bottom electrode structure and the MTJ-containing pillar.

In some embodiments, the memory device of FIG. 23 further includes a diffusion barrier liner (i.e., second diffusion barrier liner 46) located on a sidewall and a bottom surface of the second electrically conductive structure 48.

In some embodiments, the multilayered bottom electrode structure includes two bottom electrodes (e.g., first bottom electrode 25 and second bottom electrode 27) that are in intimate contact with each other.

In some embodiments, the two bottom electrodes (e.g., first bottom electrode 25 and second bottom electrode 27) are composed of compositionally different conductive metal-containing materials.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A memory device comprising:
a first electrically conductive structure;
a metal cap located on the first electrically conductive structure;
a magnetic tunnel junction (MTJ)-containing pillar located above the metal cap;
a bottom electrode having a serpentine pattern located between the metal cap and the MTJ-containing pillar, wherein the bottom electrode has a bottommost surface that is in contact with the metal cap and a topmost surface in contact with the MTJ-containing pillar;
a top electrode located on the MTJ-containing pillar; and
a second electrically conductive structure electrically connected to the top electrode.

2. The memory device of claim 1, wherein the MTJ-containing pillar comprises a bottom magnetic material containing layer, a tunnel barrier layer and an upper magnetic material containing layer, wherein the bottom magnetic material containing layer comprises a magnetic free material, and the upper magnetic material containing layer comprises a magnetic reference material.

3. The memory device of claim 1, wherein the MTJ-containing pillar comprises a bottom magnetic material containing layer, a tunnel barrier layer and an upper magnetic material containing layer, wherein the bottom magnetic material containing layer comprises a magnetic reference material, and the upper magnetic material containing layer comprises a magnetic free material.

4. The memory device of claim 1, wherein the top electrode and the MTJ-containing pillar are laterally surrounded by an encapsulation liner.

5. The memory device of claim 1, further comprising a multi-layered ILD containing region located adjacent to, and embedding, the bottom electrode.

6. The memory device of claim 1, further comprising a gap filling ILD layer located in each gap created by the serpentine pattern of the bottom electrode.

7. The memory device of claim 1, wherein the MTJ-containing pillar has a sidewall that is vertically aligned with a sidewall of the top electrode, and the vertically aligned sidewalls of the MTJ-containing pillar and the top electrode extend beyond an outermost sidewall of the bottom electrode.

8. The memory device of claim 1, wherein the bottom electrode having the serpentine pattern comprises multiple hills and valleys, wherein each hill is in electrical contact with the MTJ-containing pillar, and each valley is in electrical contact with the metal cap.

9. The memory device of claim 1, wherein the bottom electrode having the serpentine pattern comprises a single hill and a single valley, wherein the single hill is in electrical contact with the MTJ-containing pillar, and the single valley is in electrical contact with the metal cap.

10. The memory device of claim 1, further comprising a diffusion barrier liner located on a sidewall and a bottom surface of the second electrically conductive structure.

11. A memory device comprising:
a first electrically conductive structure;
a metal cap located on the first electrically conductive structure;
a magnetic tunnel junction (MTJ)-containing pillar located above the metal cap;
a multilayered bottom electrode structure having a serpentine pattern located between the metal cap and the MTJ-containing pillar, wherein multilayered bottom electrode structure has a bottommost bottom electrode in contact with the metal cap and a topmost bottom electrode in contact with the MTJ-containing pillar;
a top electrode located on the MTJ-containing pillar; and
a second electrically conductive structure electrically connected to the top electrode.

12. The memory device of claim 11, wherein the MTJ-containing pillar comprises a bottom magnetic material containing layer, a tunnel barrier layer and an upper magnetic material containing layer, wherein the bottom magnetic material containing layer comprises a magnetic free material, and the upper magnetic material containing layer comprises a magnetic reference material.

13. The memory device of claim 11, wherein the MTJ-containing pillar comprises a bottom magnetic material containing layer, a tunnel barrier layer and an upper magnetic material containing layer, wherein the bottom magnetic material containing layer comprises a magnetic reference material, and the upper magnetic material containing layer comprises a magnetic free material.

14. The memory device of claim 11, wherein the top electrode and the MTJ-containing pillar are laterally surrounded by an encapsulation liner.

15. The memory device of claim 11, further comprising a multi-layered ILD containing region located adjacent to, and embedding, the multilayered bottom electrode structure.

16. The memory device of claim 11, further comprising a gap filling ILD layer located in each gap created by the serpentine pattern of the multilayered bottom electrode structure.

17. The memory device of claim 11, wherein the MTJ-containing pillar has a sidewall that is vertically aligned with a sidewall of the top electrode, and the vertically aligned sidewalls of the MTJ-containing pillar and the top electrode extend beyond an outermost sidewall of the multilayered bottom electrode structure.

18. The memory device of claim 11, wherein the bottommost bottom electrode comprises multiple hills and valleys, wherein each valley of the multiple hills and valleys of the bottommost bottom electrode is in electrical contact with the metal cap, and the topmost bottom electrode comprises multiple hills and valleys, wherein each hill of the multiple hills and valleys of the topmost bottom electrode is in electrical contact with the MTJ-containing pillar.

19. The memory device of claim 11, wherein the bottommost bottom electrode comprises a single hill and a single valley, wherein the single valley of the bottommost bottom electrode is in electrical contact with the metal cap, and the topmost bottom electrode comprises a single hill and a single valley, wherein the single hill of the topmost bottom electrode is in electrical contact with the MTJ-containing pillar.

20. The memory device of claim 11, further comprising a diffusion barrier liner located on a sidewall and a bottom surface of the second electrically conductive structure.

21. The memory device of claim 11, wherein the multilayered bottom electrode structure comprise two bottom electrodes that are in intimate contact with each other.

22. The memory device of claim 21, wherein the two bottom electrodes are composed of compositionally different conductive metal-containing materials.
